(19) United States
(12) Patent Application Publication
(10) Pub. No.: US 2019/0108873 A1
(43) Pub. Date: Apr. 11, 2019

(54) INTEGRATED CIRCUITS INCLUDING A STATIC RANDOM ACCESS MEMORY CELL HAVING ENHANCED READ/WRITE PERFORMANCE, METHODS OF FORMING THE INTEGRATED CIRCUITS, AND METHODS OF OPERATING THE INTEGRATED CIRCUITS

(71) Applicant: GLOBALFOUNDRIES, Inc., Grand Cayman (KY)

(72) Inventors: Hui Zang, Malta, NY (US); Josef Watts, Malta, NY (US)

(21) Appl. No.: 15/729,067

(22) Filed: Oct. 10, 2017

(51) Int. Cl. G11C 11/419; G11C 11/418; H01L 27/11; H01L 29/78; G11C 11/412; H01L 21/8238

(52) U.S. Cl. CPC G11C 11/419; G11C 11/418; H01L 27/1104; H01L 29/7851; H01L 23/528; H01L 21/823821; H01L 21/823871; H01L 21/823828; G11C 11/412

(57) ABSTRACT

Integrated circuits including a static random access memory (SRAM) cell, methods of operating the same, and methods of fabricating the same are provided herein. In an embodiment, an integrated circuit includes the SRAM cell. The SRAM cell includes a first pass-gate transistor and a second pass-gate transistor. The SRAM cell further includes a first word line and a second word line. The first word line and the second word line are electrically independent of each other. The first pass-gate transistor and/or the second pass-gate transistor include a first gate in electrical communication with the first word line and a second gate in electrical communication with the second word line with the first gate and the second gate included in the same pass-gate transistor.

### TECHNICAL FIELD

The technical field generally relates to integrated circuits that include a static random access memory (SRAM) cell, methods of forming the integrated circuits, and methods of operating the integrated circuits. More particularly, the technical field relates to integrated circuits that include a SRAM cell having enhanced read/write performance, and methods of forming and operating the integrated circuits.

### BACKGROUND

Static random access memory (SRAM) is a type of volatile semiconductor memory for storing binary logic “1” and “0”. The SRAM cells can retain information stored therein during supply of power to the SRAM cells, with the cells losing the retained information upon discontinuing power to the SRAM cells.

Referring to FIG. 1, one common configuration of an integrated circuit 10 that includes a SRAM cell 13 is shown, with the SRAM cell 13 being a six transistor memory cell with a first inverter 11 and a second inverter 12 cross-coupled to the first inverter 11. Specifically, SRAM cell 13 includes a first pull-up transistor 21 and a second pull-up transistor 22, a first pull-down transistor 31 and a second pull-down transistor 32, and a first pass-gate transistor 41 and a second pass-gate transistor 42. The first pull-up transistor 21 and the first pull-down transistor 31 form the first inverter 11. The second pull-up transistor 22 and the second pull-down transistor 32 form the second inverter 12. A first bit line 51 is in direct electrical communication with the first pass-gate transistor 41. Further, a second bit line 52 is in direct electrical communication with the second pass-gate transistor 42. The first bit line 51 and the second bit line 52 are independently controllable to apply voltages of different values. Also, a word line 60 is provided and is in direct electrical communication with both the first pass-gate transistor 41 and the second pass-gate transistor 42. The word line 60 may be controlled to apply a voltage on each of the pass-gate transistors 41, 42 sufficient to open the pass-gate transistors 41, 42. In this regard, the pass-gate transistors 41, 42 are subject to the same applied voltage when voltage is applied to the word line 60 but with the pass-gate transistors in electrical communication with and under separate control of the respective first bit line 51 and second bit line 52. Selective application of voltage to the word line 60 and the respective bit lines 51, 52 is employed to write information to and read information from the SRAM cell 13 in accordance with well-known conventions.

In the SRAM cells 13, cell stability and cell writability are important and competing considerations. Cell stability, or the tendency of the SRAM cell to be altered during read access, generally correlates to a “beta ratio” of current delivered by the pull-down transistor (“Ion PD”) over current delivered by the pass-gate transistors (“Ion PG”). Higher relative Ion PG as compared to Ion PD leads to lower cell stability. As such, higher Ion PD as compared to Ion PG is desired to promote cell stability. Cell writability, which is a measure of how quickly a state of the SRAM cell can be changed during writing, generally correlates to a “gamma ratio” of Ion PG over the Ion of the pull up transistor. A failure to write may occur when Ion PG is not high enough to overpower Ion PU and pull an internal node of a memory cell to ground (writing “0”). As such, high Ion PG as compared to Ion PU is desired to promote cell writability. Because the pull-down transistors and the pull-up transistors are subject to the same current inputs during read access and writing in conventional SRAM cells, the beta ratio and the gamma ratio are generally in direct conflict and the various transistors are designed to achieve an acceptable balance between the beta ratio and the gamma ratio.

Accordingly, it is desirable to provide improved integrated circuits that include a SRAM cell, methods of operating the integrated circuits, and method of forming the integrated circuits that include the SRAM cell having enhanced read/write performance. Furthermore, other desirable features and characteristics will become apparent from the subsequent detailed description and the appended claims, taken in conjunction with the accompanying drawings and this background.

### BRIEF SUMMARY

Integrated circuits including a static random access memory (SRAM) cell, methods of operating the same, and methods of fabricating the same are provided herein. In an embodiment, an integrated circuit includes the SRAM cell. The SRAM cell includes a first pass-gate transistor and a second pass-gate transistor. The SRAM cell further includes a first word line and a second word line. The first word line and the second word line are electrically independent of each other. The first pass-gate transistor and/or the second pass-gate transistor include a first gate in electrical communication with the first word line and a second gate in electrical communication with the second word line with the first gate and the second gate included in the same pass-gate transistor.

In another embodiment, a method of operating an integrated circuit that includes a SRAM cell is provided. The method includes providing the SRAM cell with a first word line, a second word line that is electrically independent of the first word line, a first pass-gate transistor, and a second pass-gate transistor. The first pass-gate transistor includes a first gate in electrical communication with the first word line and a second gate in electrical communication with the second word line. The second pass-gate transistor includes a first gate in electrical communication with the first word line and a second gate in electrical communication with the second word line. A primary voltage is applied to the first word line and a secondary voltage to the second word line, and a write operation is performed to save a selected value in the SRAM cell during applying of the primary voltage to the first word line and the secondary voltage to the second word line. Only one of the primary voltage is applied to the first word line or the secondary voltage is applied the second word line, and a read operation is performed to retrieve the selected value in the SRAM cell during applying of the primary voltage to the first word line or the secondary voltage to the second word line.

In another embodiment, a method of forming an integrated circuit that includes a SRAM cell is provided. The method includes providing a partially fabricated SRAM cell that includes a plurality of semiconductor fins that include a channel region. A gate stack is disposed over and extends along opposing sidewalls of the semiconductor fins, with a top surface of the gate stack on even plane with or below a top surface of the semiconductor fins. The gate stack includes a lower dielectric layer, an upper dielectric layer, and a gate electrode layer disposed between the lower and upper dielectric layers. The gate stack is patterned at a pass-gate transistor location to separate portions of the gate stack on the opposing sidewalls of the corresponding semiconductor fins and to produce a first gate and a second gate separated by the semiconductor fin and isolated from each other. The first and second gates are included in the same pass-gate transistor.

### BRIEF DESCRIPTION OF THE DRAWINGS

The various embodiments will hereinafter be described in conjunction with the following drawing figures, wherein like numerals denote like elements, and wherein:

FIG. 1 schematically illustrates a conventional static random access memory (SRAM) cell including six transistors (6T) in accordance with the prior art;

FIG. 2 schematically illustrates a 6T SRAM cell in accordance with an embodiment of the present disclosure;

FIG. 3 is a schematic cross-sectional side view of a pass-gate transistor of FIG. 2 in accordance with an embodiment; and

FIG. 4 is a schematic top view of a partially-fabricated integrated circuit including a 6T SRAM cell at an intermediate stage of fabrication in accordance with an embodiment.

### DETAILED DESCRIPTION

The following detailed description is merely exemplary in nature and is not intended to limit the integrated circuits that include a SRAM cell, methods of forming the integrated circuits, or methods of operating the integrated circuits. Furthermore, there is no intention to be bound by any theory presented in the preceding background or the following detailed description.

Embodiments of the present disclosure are generally directed to integrated circuits and methods for fabricating the same. For the sake of brevity, conventional techniques related to integrated circuit fabrication may not be described in detail herein. Moreover, the various tasks and process steps described herein may be incorporated into a more comprehensive procedure or process having additional steps or functionality not described in detail herein. In particular, various steps in the manufacture of semiconductor-based transistors are well-known and so, in the interest of brevity, many conventional steps will only be mentioned briefly herein or will be omitted entirely without providing the well-known process details.

The drawings are semi-diagrammatic and not to scale and, particularly, some of the dimensions are for the clarity of presentation and are shown exaggerated in the drawings. Similarly, although the views in the drawings for ease of description generally show similar orientations, this depiction in the drawings is arbitrary. As used herein, it will be understood that when a first element or layer is referred to as being “over” or “under” a second element or layer, the first element or layer may be directly on the second element or layer, or intervening elements or layers may be present. When a first element or layer is referred to as being “on” a second element or layer, the first element or layer is directly on and in contact with the second element or layer.

Generally, the integrated circuit can be operated in any orientation. Spatially relative terms, such as “top”, “bottom”, “over” and “under” are made in the context of the various views in the Figures for ease of description to describe one element or feature's relationship to the other features as shown in the various views. It will be understood that the spatially relative terms are intended to encompass different orientations of the integrated circuit in use or operation in addition to the orientation depicted in the figures. Thus, the exemplary terms “over” and “under” can each encompass either an orientation of above or below depending upon the orientation of the integrated circuit. The integrated circuit may be otherwise oriented (e.g., rotated 90 degrees or at other orientations) and the spatially relative descriptors used herein may likewise be interpreted accordingly.

As alluded to above, integrated circuits that include a SRAM cell, methods of forming the integrated circuits, and methods of operating the integrated circuits are provided herein. The SRAM cell includes a first pass-gate transistor, a second pass-gate transistor, and inverters. However, unlike conventional SRAM cell architecture, the SRAM cells as described herein include the first pass-gate transistor and/or the second pass-gate transistor with a first gate in electrical communication with a first word line and a second gate in electrical communication with a second word line, with the first and second word lines electrically independent of each other. Namely, the first pass-gate transistor and/or the second pass-gate transistor each include the first and second gates such that the first pass-gate transistor and/or the second pass-gate transistor are under the electrical influence of two gates. With the aforementioned configuration of the pass-gate transistors, voltage applied to the pass-gate transistors can be adjusted depending upon the operation performed (e.g., read or write), with relatively higher current delivered by the pass-gate transistor(s) during writing by applying voltage to both the first and second pass gates and relatively lower current delivered by the pass-gate transistor(s) during reading by applying voltage to only one of the first or second pass gates. As a result, both excellent read performance can be achieved (relatively lower current to the pass-gate transistors increases a relative beta ratio of the SRAM cell during reading) and excellent write performance can be achieved (relatively higher current to the pass-gate transistor(s) increases a relative gamma ratio of the SRAM cell during writing).

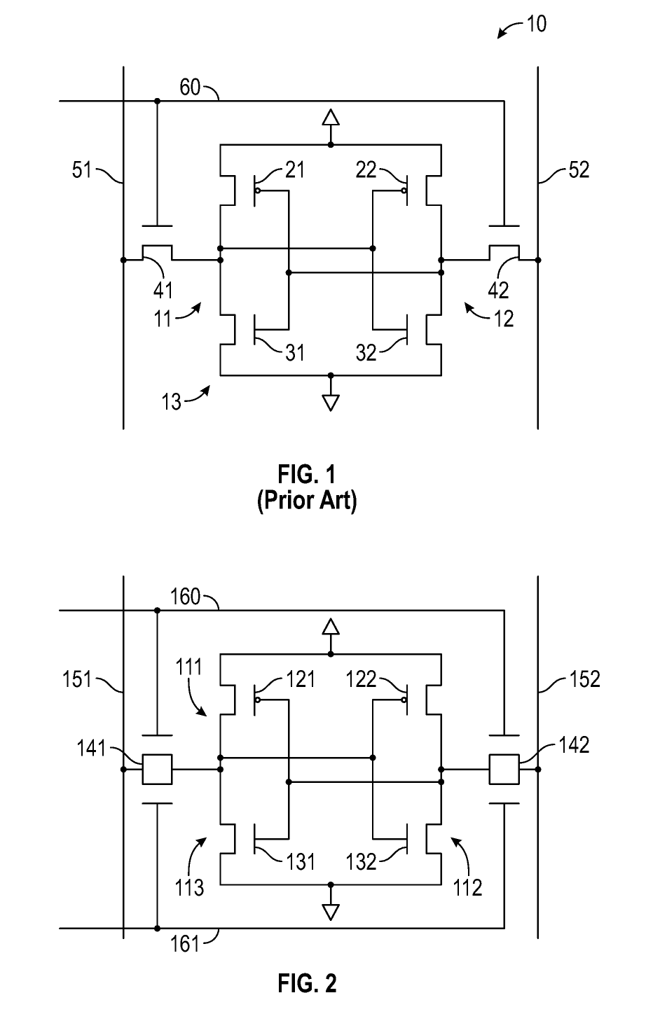

Referring to FIG. 2, an exemplary embodiment of an integrated circuit 110 including a SRAM cell 113 will now be described in detail. In the embodiment as shown, the SRAM cell 113 is a six transistor (6T) memory cell with a first inverter 111 and a second inverter 112 cross-coupled to the first inverter 111. Specifically, SRAM cell 113 includes a first pull-up transistor 121 and a second pull-up transistor 122, a first pull-down transistor 131 and a second pull-down transistor 132, and a first pass-gate transistor 141 and a second pass-gate transistor 142. The first pull-up transistor 121 and the first pull-down transistor 131 form the first inverter 111. The second pull-up transistor 122 and the second pull-down transistor 132 form the second inverter 112.

In an exemplary embodiment, the first pull-up transistor 121 is a P-type field effect transistor (PFET) and the second pull-up transistor 122 is a P-type field effect transistor (PFET). Further, the exemplary first pull-down transistor 131 is an N-type field effect transistor (NFET) and the exemplary second pull-down transistor 132 is an N-type field effect transistor (NFET). In an exemplary embodiment, each pass-gate transistor 141 and 142 is an N-type field effect transistor (NFET).

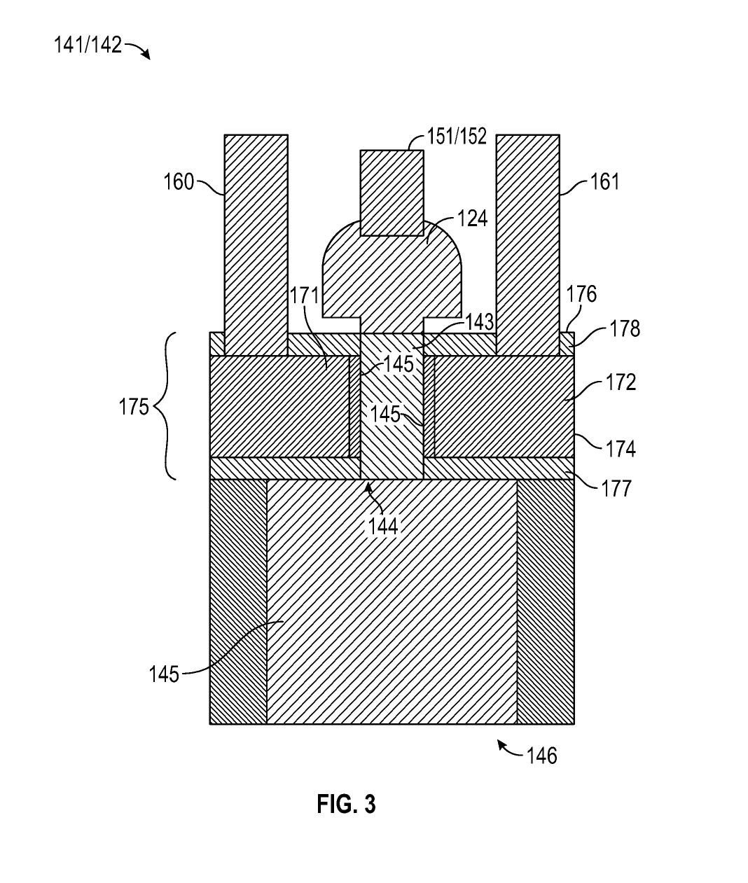

A first bit line 151 is in direct electrical communication with the first pass-gate transistor 141. Further, a second bit line 152 is in direct electrical communication with the second pass-gate transistor 142. More particular, referring momentarily to FIG. 3, the respective bit lines 151, 152 are in direct electrical communication with a respective source/drain region 124 of the corresponding pass-gate transistors 141, 142. The first bit line 151 and the second bit line 152 are independently controllable to apply voltages of different values during read/write operations, in accordance with conventional operation of SRAM cells.

A first word line 160 and a second word line 161 are provided. The first word line 160 and the second word line 161 are electrically independent of each other, i.e., a voltage is capable of being applied to one of the first or second word lines 160, 161 without the other of the first or second word lines 160, 161 taking on the applied charge. Referring momentarily to FIG. 3, the first pass-gate transistor 141 and/or the second pass-gate transistor 142 include a first gate 171 and a second gate 172, with the first word line 160 in direct electrical communication with and, optionally, physically contacting the first pass gate 171 and with the second word line 161 in direct electrical communication with and, optionally, physically contacting the second gate 172. By “direct electrical communication,” it is meant that the elements so connected do not have intervening devices disposed therebetween, with only features necessary to facilitate electrical connection disposed therebetween. The first pass gate 171 and the second pass gate 172 are associated with a common channel region 143, with the first pass gate 171 and the second pass gate 172 as referred to throughout herein included in the same pass-gate transistor 141, 142. In embodiments, one of the first pass-gate transistor 141 or the second pass-gate transistor 142 includes the first pass gate 171 and the second pass gate 172, or both of the first pass-gate transistor 141 and the second pass-gate transistor 142 include the first pass gate 171 and the second pass gate 172.

As set forth above, voltage applied to pass-gate transistors 141, 142 that include the first gate 171 and the second gate 172 can be adjusted depending upon the operation performed (e.g., read or write), with relatively higher current delivered to the pass-gate transistor(s) 141, 142 during writing by applying voltage to both the first and second gates 171, 172 from the respective word lines 160, 161 and relatively lower current delivered to the pass-gate transistor(s) 141, 142 during reading by applying voltage to only one of the first or second gates 171, 172. In this regard, the SRAM cell 113 can be designed with higher current delivered by the pass-gate transistor(s) 141, 142 (“Ion PG”), leading to higher gamma ratio and improved writability, while also enabling lower Ion PG to be supplied by the pass-gate transistor(s) 141, 142 during reading, leading to higher beta ratio and improved cell stability. For example, the word lines 160, 161 may be separately controlled to independently apply a voltage on the respective pass-gate transistors 141, 142 sufficient to open the pass-gate transistors 141, 142. However, the applied voltage on the respective pass-gate transistors 141, 142 can be varied depending upon whether one of the word lines 160, 161 or both of the word lines 160, 161 are turned on. In this regard, the pass-gate transistors 41, 42 may be subject to the same applied voltage when voltage is applied to the word lines 160, 161 but with the pass-gate transistors 141, 142 in electrical communication with and under separate control of the respective bit lines 151, 152. Selective application of voltage to the word lines 160, 161 and the respective bit lines 151, 152 may be employed to write information to and read information from the SRAM cell 113, with one of the word lines 160, 161 turned off during reading to effectively lower the current through the pass-gate transistors 141, 142.

In embodiments and as shown in FIG. 3, the first gate 171 and the second gate 172 are disposed laterally adjacent to the channel region 143 of the respective pass-gate transistor(s) 141, 142. More particular, in this embodiment, a single semiconductor fin 144 includes the channel region 143 with the first gate 171 and the second gate 172 disposed over and extending along opposing sidewalls 145 of the single semiconductor fin 144. The source/drain region 124 in electrical communication with the bit lines 151, 152 is formed on the single semiconductor fin 144, and an opposing source/drain region 125 is formed on an opposite side of the gates 171, 172 from the source/drain region 124. The opposing source/drain region 125 is formed in a semiconductor substrate 146, with the semiconductor fins 144 extending from the semiconductor substrate 146. In this regard the pass-gate transistors 141, 142 are vertically oriented, due to the position of the gates 171, 172 laterally adjacent to the channel region 143 in the single semiconductor fin 144, and further due to the opposing source/drain regions 124, 125 disposed on opposite sides of the gates 171, 172 above and below the channel 143.

As used herein, the term “semiconductor substrate” will be used to encompass semiconductor materials that are conventionally used in the semiconductor industry. “Semiconductor materials” include monocrystalline silicon materials, such as relatively pure or lightly impurity-doped monocrystalline silicon materials typically used in the semiconductor industry, as well as polycrystalline silicon materials, and silicon admixed with other elements such as germanium, carbon, and the like. In addition, “semiconductor material” encompasses other materials such as relatively pure and impurity-doped germanium, gallium arsenide, zinc oxide, glass, and the like.

A method of operating the integrated circuit 110 that includes the SRAM cell 113 will now be described in accordance with an embodiment, with continued reference to FIGS. 2 and 3. In accordance with the exemplary method, the SRAM cell 113 as described above is provided with the SRAM cell 113 including the first word line 160, the second word line 161 that is electrically independent of the first word line 160, the first pass-gate transistor 141 that includes the first gate 171 in electrical communication with the first word line 160 and the second gate 172 in electrical communication with the second word line 161, and the second pass-gate transistor 142 that includes the first gate 171 in electrical communication with the first word line 160 and the second gate 172 in electrical communication with the second word line 161. First and second bit lines 151, 152 are also provided as described above. A write operation is performed to save a selected value in the SRAM cell 113. More particularly, a primary voltage is applied to the first word line 160 and a secondary voltage is applied to the second word line 161, and the write operation is performed during applying of the primary voltage to the first word line 160 and the secondary voltage to the second word line 161. In this regard, Ion PG is maximized due to voltage being applied to both the first and second word lines 160, 161.

A voltage at a first value may be applied to the first pass-gate transistor 141 through the first bit line 151, while a voltage at a second value may be applied to the second pass-gate transistor 142 through the second bit line 152. Generally, the first value may be logic LOW voltage, such as “0”, or logic HIGH voltage, such as “1”. Likewise, the second value may be a logic HIGH voltage, such as “1”, or a logic LOW voltage, such as “0”. The first bit line 51 and the second bit line 52 are independently controllable to apply signals of different values. Data to be written into the SRAM cell 113 is applied to the bit lines 151, 152, with the word lines 160, 161 effecting opening of the pass-gate transistors 141, 142. Writing data to the SRAM cell 113 may proceed through conventional techniques.

A read operation is performed to retrieve the selected value in the SRAM cell 113. More particularly, one of the primary voltage is applied to the first word line 160 or the secondary voltage is applied to the second word line 161. Unlike the write operation, only one of the primary voltage or the secondary voltage is applied, resulting in a lower Ion PG than during writing and thereby maximizing cell stability. The read operation is performed during applying of the primary voltage to the first word line 160 or the secondary voltage to the second word line 161.

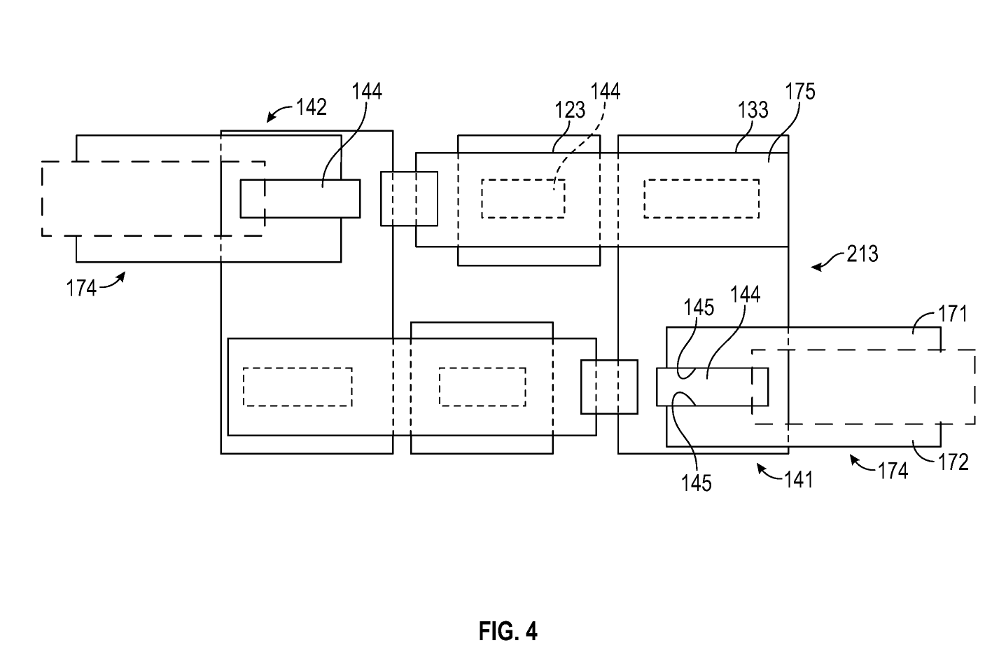

A method of forming the integrated circuit 110 that includes the SRAM cell 113 will now be described in accordance with an embodiment and with reference to FIG. 4 and continued reference to FIG. 3. FIG. 4 illustrates a partially fabricated SRAM cell 213 at an intermediate stage of fabrication, during gate patterning and prior to back-end-of-line (BEOL) processing. More particularly, the partially fabricated SRAM cell 213 is shown including a plurality of semiconductor fins 144. A gate stack 175 is disposed over and extends along opposing sidewalls 145 of the semiconductor fins 144. As best illustrated in FIG. 3, a top surface 176 of the gate stack 175 is on even plane with or below a top surface of the semiconductor fins 144. The gate stack 175 includes a lower dielectric layer 177, an upper dielectric layer 178, and a gate electrode layer 179 disposed between the lower and upper dielectric layers 177, 178.

As shown in FIG. 4, the gate stack 175 is patterned at a pass-gate transistor location 174 to separate portions of the gate stack 175 on the opposing sidewalls 145 of the corresponding semiconductor fins 144 and to produce a first gate 171 and a second gate 172. The first and second gates 171, 172 are separated by the semiconductor fin 144 and are isolated from each other, but are included in the same pass-gate transistor 141, 142. More specifically, prior to patterning, the gate stack 175 may be disposed adjacent to at least three sides of the semiconductor fin 144, and patterning splits the gate stack 175 at the pass-gate transistor location 174. It is to be appreciated that in embodiments, patterning the gate stack 175 at the pass-gate transistor location 174 may be conducted as an added patterning step, after patterning the gate stack 175 to form pull-up gates 123 and pull-down gates 133 of the respective pull-up and pull-down transistors. Alternatively, the gate stack 175 may be patterned at the pass-gate transistor location 174 in the manner described above during patterning of the gate stack 175 to form other gates, e.g., during patterning to form pull-up gates 123 and pull-down gates 133 of the respective pull-up and pull-down transistors.

After patterning the gate stack 175, fabrication of the integrated circuit may proceed by forming the source/drain region 124 on the semiconductor fins 144 and then conducting BEOL fabrication steps including forming the bit lines 151, 152 and word lines 160, 161 in the configurations as described above.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration in any way. Rather, the foregoing detailed description will provide those skilled in the art with a convenient road map for implementing an exemplary embodiment. It being understood that various changes may be made in the function and arrangement of elements described in an exemplary embodiment without departing from the scope as set forth in the appended claims.

1. An integrated circuit comprising:
a static random access memory (SRAM) cell, wherein the SRAM cell comprises a first pass-gate transistor and a second pass-gate transistor;
a first word line; and
a second word line, wherein the first word line and the second word line are electrically independent of each other;
wherein the first pass-gate transistor and/or the second pass-gate transistor comprise a first gate in electrical communication with the first word line and a second gate in electrical communication with the second word line with the first gate and the second gate included in the same pass-gate transistor,.
wherein the first gate and the second gate are associated with a common channel region of the respective pass-gate transistors and are disposed laterally adjacent to the channel region of the respective pass-gate transistors;
wherein a single semiconductor fin includes the channel region for the respective pass-gate transistors with the first gate and the second gate disposed over and extending along opposing sidewalls thereof and with the semiconductor fin extending from a semiconductor substrate,
wherein the pass-gate transistors are vertically oriented with a source/drain region of the pass-gate transistors formed on the single semiconductor fin and an opposing source/drain region of the pass-gate transistors formed in the semiconductor substrate on an opposite side of the gates from the source/drain region.

2. The integrated circuit of claim 1, wherein the first pass-gate transistor and the second pass-gate transistor each comprise the first gate in electrical communication with the first word line and the second gate in electrical communication with the second word line.

3. (canceled)

4. (canceled)

5. The integrated circuit of claim 2, wherein the single semiconductor fin includes the channel region for the respective pass-gate transistors with the first gate and the second gate disposed over and extending along opposing sidewalls thereof.

6. The integrated circuit of claim 5, wherein a first bit line is in direct electrical communication with the first pass-gate transistor and a second bit line is in direct electrical communication with the second pass-gate transistor.

7. The integrated circuit of claim 6, wherein the bit lines are in direct electrical communication with the respective source/drain region of the corresponding pass-gate transistors.

8. (canceled)

9. (canceled)

10. The integrated circuit of claim 1, wherein the SRAM cell is a six transistor memory cell.

11. The integrated circuit of claim 10, wherein the SRAM cell comprises a first inverter and a second inverter cross-coupled to the first inverter.

12. The integrated circuit of claim 11, wherein the SRAM cell comprises a first pull-up transistor and a first pull-down transistor that form the first inverter, and wherein the SRAM cell further comprises a second pull-up transistor and a second pull-down transistor that form the second inverter.

13. The integrated circuit of claim 12, wherein a first bit line is in direct electrical communication with the first pass-gate transistor and a second bit line is in direct electrical communication with the second pass-gate transistor.

14. The integrated circuit of claim 13, wherein the bit lines are in direct electrical communication with a respective source/drain region of the corresponding pass-gate transistors.

15. The integrated circuit of claim 14, wherein both of the first pass-gate transistor and the second pass-gate transistor include the first gate and the second gate.

16.-20. (canceled)
